(19) United States
(12) Patent Application Publication
(10) Pub. No.: US 2010/0040244 A1
(43) Pub. Date: Feb. 18, 2010

(54) METHOD AND SYSTEM FOR AUDITORY ENHANCEMENT AND HEARING CONSERVATION

(75) Inventors: Desmond Arthur Smith, Randburg Gauteng (ZA); H. Christopher Schweitzer, Lafayette, CO (US)

Correspondence Address: POLSINELLI SHUGHART PC, 700 West 47th Street, Suite 1000, KANSAS CITY, MO, 64112, US

(73) Assignee: ABLE PLANET, INCORPORATED, Wheat Ridge, CO (US)

(21) Appl. No.: 12/495,539

(22) Filed: Jun. 30, 2009

Related U.S. Application Data
(60) Provisional application No. 61/077,006, filed on Jun. 30, 2008.

(51) Int. Cl. H03G 5/00

(52) U.S. Cl. 381/98

(57) ABSTRACT

A digital and/or analog signal processing system and method for auditory enhancement and hearing conservation includes providing an audio signal with high intensity peaks, clipping the audio signal by limiting peak power to produce a clipped signal, and amplifying the clipped signal.

### RELATED APPLICATIONS

This is a U.S. Utility Application which claims the benefit of U.S. Provisional Application No. 61/077,006, filed Jun. 30, 2008, the entire contents of which are incorporated herein by reference.

### BACKGROUND OF THE INVENTION

1. Field of the Invention

The present invention relates to methods and devices for hearing enhancement, sound and noise suppression and for listening to audio and music transmissions. More particularly, the present invention relates to a method and system for modifying an audio signal using signal processing techniques to redistribute potentially damaging peak components in a manner so as to enhance soft and average level signal components, improve timbre and perceptual detail and eliminate signal distortion without an increase in volume.

2. Background Information

Recent advances in sound transmission technology have lead to the development of new and improved hearing aids, head sets, musical ear buds, telephone hand sets and other devices designed specifically to transmit sound to the human ear. Certain devices such as telephone hand sets and head sets are designed to fit over the outer ear and are held in place either by hand or by means of a head band, which frees up the hands for note taking or other activities which may be performed simultaneously while receiving information via the hand set or head set.

Other devices such as hearing aids, musical ear buds and ear plugs are inserted directly into the outer portion of the ear passage or canal and may be employed as straightforward sound transmitting systems, as in the case of the ear bud. Hearing aids, on the other hand, provide a dual function by not only transmitting sound to the ear drum, but also by enhancing the sound quality for hearing-impaired individuals and by selectively suppressing certain sound frequencies and/or modulating the amplitude of background or so-called “white noise”. Such devices may be referred to collectively as “in-the-ear devices” as opposed to “ear covering devices”, such as the head sets described above.

A primary concern for users of either an in-the-ear-device or an ear covering device is sound quality, particularly if a user is hearing-impaired. The natural tendency of a user is to turn up the volume with the belief that the sound quality and ability to hear a signal, by way of example, a musical piece or a radio voice transmission, is enhanced. However, while an increase in volume may, indeed, give the listener the perception of an increased ability to hear the transmission, in actuality, the signal clarity, bandwidth and acoustical detail, particularly at softer and mid-level sounds typical of music and speech, may in fact be degraded in quality. Moreover, an increase in volume also increases the level of very short duration peak components of an audio signal which may damage the listener's auditory system, particularly over extended periods of listening to high volume signals.

Hence, a need exists for a system which will eliminate the harmful peak components of an audio signal without inducing distortion while improving overall signal quality at all levels and enhancing the listening experience.

### SUMMARY OF THE INVENTION

It is an object of the present invention to provide a system and method for auditory enhancement and hearing conservation.

In order to achieve the above mentioned object and other objects of the present invention, a signal processing method for auditory enhancement and hearing conservation is provided that comprises controlling an audio signal having high intensity peaks, clipping the audio signal by limiting peak power to produce a clipped signal, and amplifying the clipped signal.

In addition, a signal processing system for auditory enhancement and hearing conservation is provided that comprises a processing unit, a power unit, an input socket and an output socket. The processing unit is for controlling an audio signal having high intensity peaks. The power unit is connected to the processing unit to deliver power. The input socket is operably connected to the processing unit and configured to receive the audio signal. The output socket is operably connected to the processing unit and configured to output a processed audio signal. The processing unit is configured to clip the audio signal by limiting peak power to produce a clipped signal and further configured to amplify the clipped signal.

These and other objects, features, aspects and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIG. 1 is a graph illustrating the shifting modulus of elasticity of a vibrating elastic cord of homogeneous organic material (latex);

FIG. 2 illustrates the shifting resonance of the basilar membrane in the ear of a chinchilla;

FIG. 3 illustrates brief high level excursions in a passage of music;

FIG. 4 shows detail indicating that high levels in the music passage occupy a small part of the total period;

FIG. 5 shows the music passage with the upper 10 dB of instantaneous sound pressure levels clipped off;

FIG. 6 shows the music passage with the upper 10 dB of instantaneous sound pressure levels clipped off and then amplified by 10 dB;

FIG. 7 shows a relationship between perceived loudness and time duration of sound signals;

FIG. 8 shows an embodiment of a signal processing system; and

FIG. 9. shows frequency response of a direct signal (upper curve) and the signal processing system (lower curve).

### DESCRIPTION OF THE INVENTION

The new and novel system and methodology of the instant invention overcomes the foregoing problems associated with the prior art by providing a signal processing method or system 10, which controllably limits instantaneous peak power in an audio signal using digital and/or analog signal processing in a manner which mimics the instantaneous compression characteristics of the human ear. More specifically, in an embodiment the system mimics how the human ear functions at sound levels above the area where the outer hair cells enhance gain and sharpen tuning,

Studies have demonstrated that when hearing loss originates in the cochlea, the most comfortable loudness (MCL) is shifted upwards. However, no corresponding shift in the uncomfortable loudness level (UCL) takes place, which suggests that at high audio levels, a hearing impaired human ear performs the same as a normal human ear. Conventional hearing aids incorporate a DSP processor which keeps the peak levels at the wearer's UCL but boosts quiet sounds, which would normally not be detectable to the user, to an audible level. Headphones typically are designed to keep peak audio signals at a safe level for individuals having normal hearing while simultaneously increasing loudness and widening the bandwidth.

Experiments performed on cadavers by Georg von Bekesy suggest that the human audiological system's tuning capabilities derive from the physical characteristics of the basilar membrane (BM), not from neurological processes. The BM is narrow at the high frequency end and widens toward the helicotrema. It consists of transverse elastic chords connected by tissue. At high sound pressure levels, the chords are stretched to almost twice their normal length. It has been established that elasticity (Young's modulus) increases at high stress levels in homogenous organic materials.

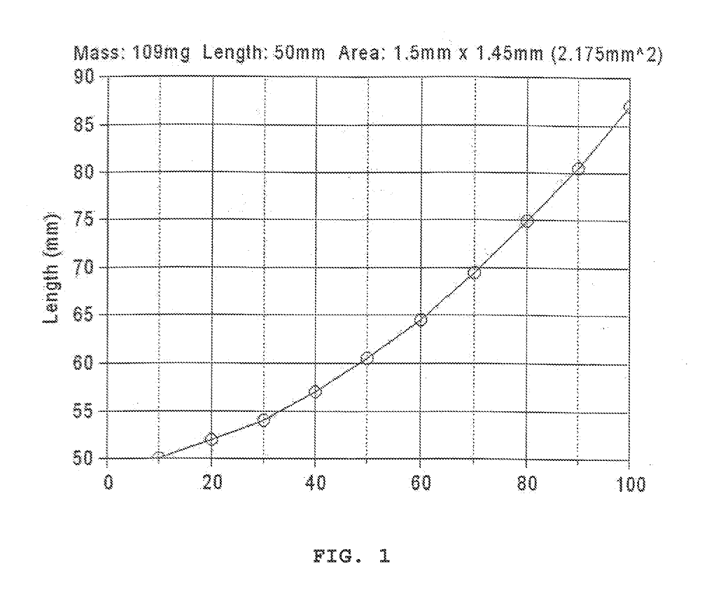

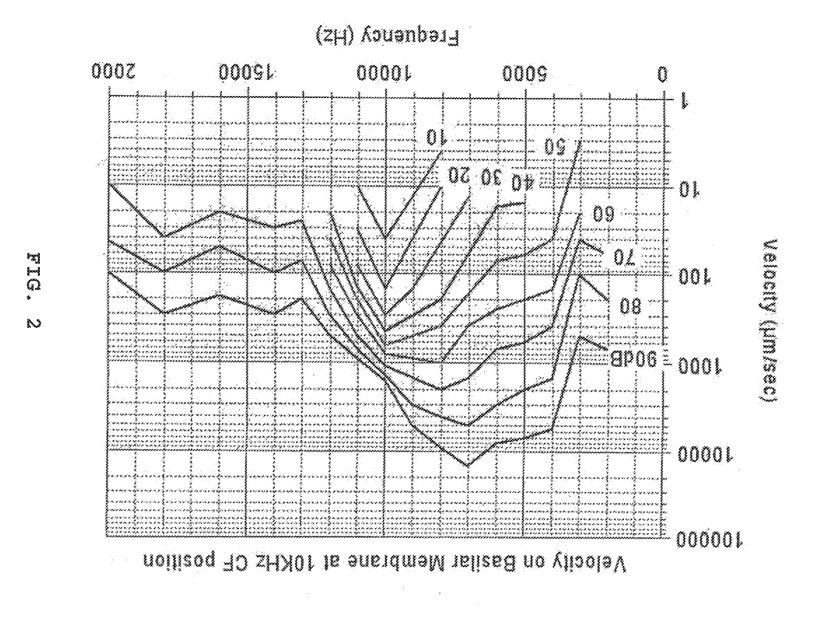

FIG. 1 illustrates the modulus of elasticity of a latex cord at various levels of loading. For constant mass but varying loading this implies a shift in resonance when applied to the elastic properties of the transverse chords on the basilar membrane in the inner ear. If elasticity is increased while the total mass remains constant, the instantaneous resonance is shifted to a lower frequency. It can be demonstrated that when a latex cord is vibrated, it exhibits tuning curves which are similar to those produced by the basilar membrane, including the widening of the tuning curve and a shift to a lower frequency at higher vibration levels. This result is suggested by the graphs of FIG. 2 from Ruggero et al. which show the measurements taken at the 10 kHz CF position in live chinchilla ears. These curves show that above approximately 45 dB sound pressure level (SPL), the resonance shifts progressively towards a lower frequency as SPL increases, which gives the erroneous impression of sound compression. The resonance shifts towards a lower frequency at higher audio levels because the instantaneous resonance depends upon the instantaneous SPL. The broadened resonance peaks are due to the shifting “instantaneous resonance” throughout the wave cycle. In effect, the hair cells in the ear are protected by spreading the energy over a wider area of the cochlea without a reduction in the total energy by, for example, heat dissipation or reflection.

Hence, as discussed in greater detail below, the method of the instant invention mimics the instantaneous compression characteristics of the human ear by using certain analog and/or digital devices, including but not limited to both electrical, mechanical and a combination of both electrical and mechanical devices to enhance audio signal quality. More specifically, the system or method of the present invention provide a significant reduction in the audio listening level with improvements in clarity and bandwidth, hearing conservation benefits while reducing distortion through a unique and novel method of peak power detection, imperceptibly slow compression to set the average gain of the signal, which is followed by instantaneous peak clipping without temporal distortions which enhance low level detail and average level richness. After the instant peak excision, a 2 msec. fast compression is applied as a backup to ensure that the level adjustments have negligible distortion.

Many amplification methods have been used that introduce negative feedback to prevent overload distortion as an alternative to hard peak clipping. The primary motivation is commonly the assumption that reduction of harmonic distortion is crucial for acceptable sound quality. Such (feedback loop) methods necessarily introduce temporal alteration (distortion) to the signal. These can be equally (or more) disturbing to the listener as the harmonic distortion they are intended to reduce. The present invention advantageously avoids these artifacts and has significant auditory benefits in its unique method of signal control and manipulation.

Contrary to common assumptions, it is possible to productively overload a dynamical complex signal so that the peak components are deliberately driven into clipping with a favorable auditory outcome. By carefully adjusting the gain to output relations, only the brief, and therefore imperceptible, peaks are clipped by saturation. The soft and average level sounds are proportionately increased to good listening advantage.

Since no feedback loop is required, this has the effect of instantaneous compression of the signal without temporal distortions. This is more analogous to the operations of the human hearing system, and arguably more perceptually natural. Studies of cochlear mechanics by Ruggerio et al (and going back to von Bekesy's Nobel Prize winning studies) provide evidence to that effect.

In regards to perceptual advantages, one of the several effects of this innovative signal treatment method is that listeners can hear low level detail and average level richness in intensively dynamic sound passages without the otherwise necessity of high level (potentially damaging) peak energy.

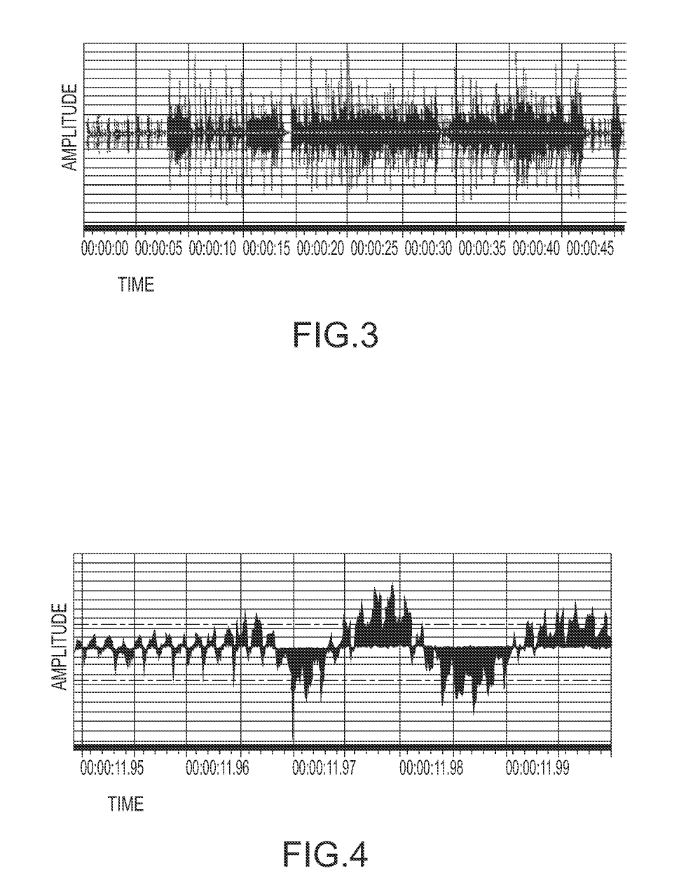

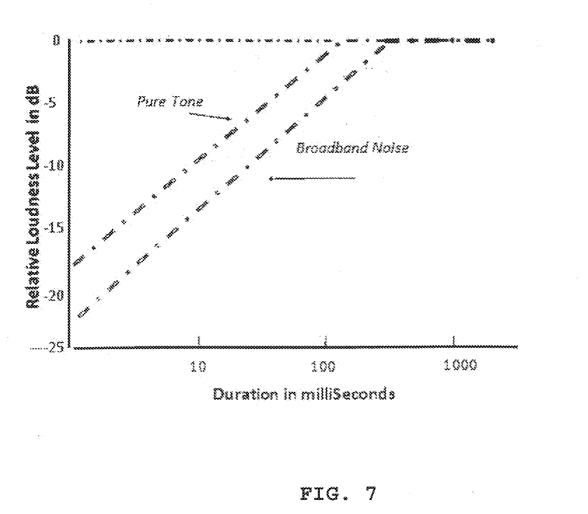

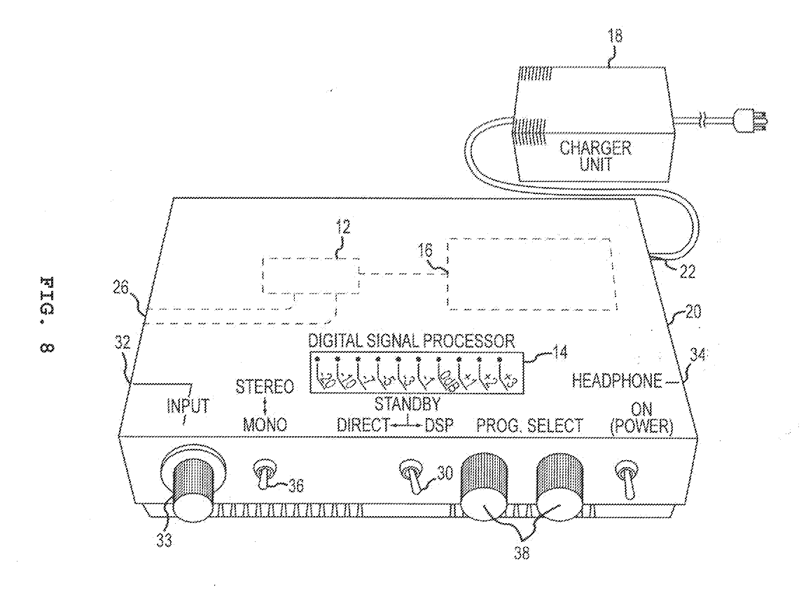

Paradoxically, an increase in average overall listening level positions the delivered sounds psychoacoustically in a flatter portion of the auditory dynamic range. While the cochlea is protected from high energy peaks, listening at generally higher levels provide improved timbre and perceptual detail. On a long term listening basis, this treatment is uniquely supportive of hearing conservation while simultaneously providing full auditory enjoyment and clarity. FIGS. 3-7 provide illustrations of the concepts and innovative signal treatment method.

Referring to FIGS. 3 and 4, the method of the present invention includes a step of precisely controlling an audio signal having high intensity peaks. FIG. 3 is an example of a recorded passage of music illustrating how the majority of the time the average energy is 10 dB below the peaks. Temporal Integration properties of the auditory system results in significantly less loudness for these brief duration components than for sounds with longer times.

FIG. 4 is a zoomed image illustrating that the contribution to total power by excursions above −10 dB is less than half the power contributed by signal levels 10 dB below maximum. Since the total period in which the brief transients occur is only about 10 msec, or 1/20th of the 100 msec loudness integration window, the levels above −10 dB will contribute no more than 1/40th of the total power in the 200 msec integration window, resulting in a loudness increase of 20 log (1+ 1/40) or 0.2 dB. It is important to recognize that while these high intensity peaks may be inaudible, they can still be damaging to hair cells of the cochlea.

Referring to FIG. 5, the method of the present invention further includes a step of clipping the audio signal by limiting peak power to produce a clipped signal. FIG. 5 shows the signal with 10 dB clipping by instantaneous limiting of peak power. The ‘loudness’ is not significantly reduced by removing the peaks. However, the potentially damaging spikes have been excised.

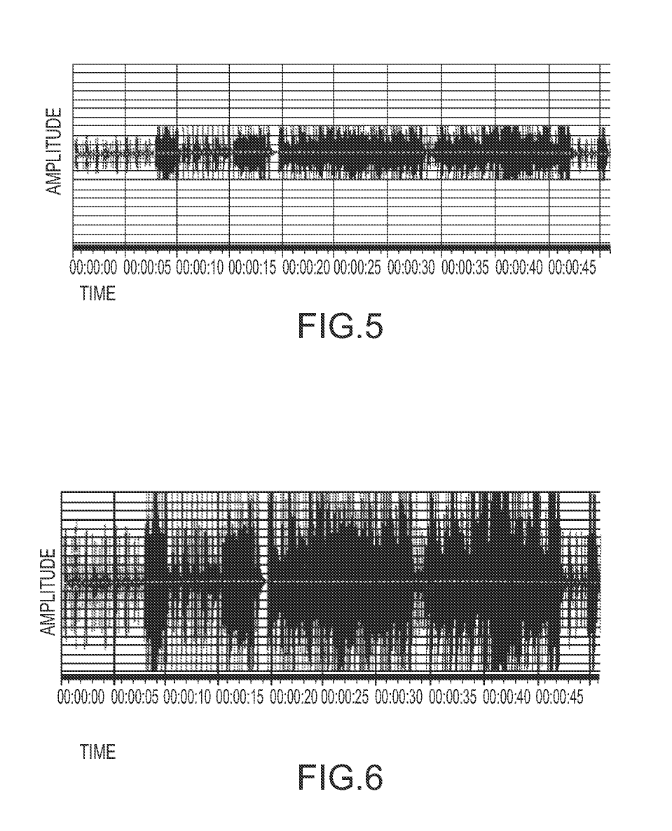

Referring to FIG. 6, the method of the present invention additionally includes a step of amplifying the clipped signal of FIG. 5. FIG. 6 shows the signal amplified after clipping (or overdriven by 10 dB). Average levels of long duration signals are increased resulting in increased loudness. This allows the ear to operate in a region where the frequency range is wider. By means of this treatment the perceived loudness of potentially damaging levels is more easily recognized as such to a listener. This results from the fact that there are no inaudible high level transients as in signals without this treatment.

This method or system of the present invention productively exploits the psychoacoustic property of temporal integration in human audition. Audibility, and proportionately, loudness, of brief duration sounds is strongly dependent upon duration for signal of less than 500 milliseconds. Psychoacoustic research, such as that of Zwislocki (1969) consistently shows a rapid decline in audibility and loudness for signals until they become asymptotic at or near 200-500 milliseconds. From the figures, it can be seen that energy (such as brief peaks) of less than 10 milliseconds are 20 dB or more less loud than longer duration samples of the same signal. This helps explain why the energetic spikes in the audio sample illustrated in FIGS. 3 and 4 are largely imperceptible. Furthermore, this method uniquely allows the listener to adjust the level to a more favorable portion of the Equal Loudness Contour illustrated in the classical figure of Fletcher & Munson. The present invention provides the rarely mentioned advantage of an increased perceptual bandwidth. This has the advantage of a flatter frequency relation which produces more audible auditory details (timbre) and a richer hearing experience.

The present invention utilizes a relation of inter-frequency (equal loudness) relations of the auditory system for listening at higher regions of the dynamic range that provides a wider bandwidth of acoustical detail and improves perception of timbre.

The system and method of the present invention controls the relation of peak acoustical energy to the long term average. It is a powerful, new approach that does not require a feedback loop (and associated temporal distortions) common with prior methods. This innovative manipulation produces several important consequences and advantages.

First, it is instantaneous. The signal is deliberately increased to a controlled and calculated extent into an overload condition that clips only the briefest, inaudible spikes.

It additionally then increases the softer and medium level components of intensively dynamic waveforms (typical of music and speech). This raises the perceived loudness and improves the listening experience by the expanded frequency sensitivity pattern that occurs in the auditory regions with flatter equal loudness properties as long reflected in the data pattern of Fletcher and Munson and others.

Hearing conservation is supported by the elimination of high energy peaks of brief duration. The effective compression of soft, medium and loud components of dynamic signals safely locates preferred listening levels to a richer psychoacoustic region, proving greater acoustical detail and bandwidth—with less damaging peak intensities. The vowel/consonant ratio is improved by this compression without the envelope distortion associated with other “AGC” methods. The vowel/consonant ratio is enhanced and the spectrum flattened without biasing frequency response to “tinny” quality.

More advantageously, soft ambient sounds are reduced by ˜10 dB without pumping distortions common with adaptive methods. Furthermore, the peak detection & averaging accomplished via exponential adaptation time is imperceptibly slow and has a rapid change after a silent period. The average peak energy determined in analysis is about 67% (−3 dB), for example, of final peak level. This is determined instantaneously or within 2 msec for signals with a fast onset and decay and within 100-200 msec for signals with slow onset and decay.

By way of example, an embodiment of a signal processing system 10 that performs the features and advantages described above and in the following examples is illustrated in FIG. 8. It will be apparent to one of ordinary skill in the art from this disclosure that the signal processing system 10 is but one embodiment for implementing the invention, which provides auditory enhancement and hearing conservation by precisely controlling an audio signal, clipping and amplifying the signal, as described above with reference to FIGS. 3-7. The signal processing system 10 includes at least one processing unit 12, a VU meter 14, a power unit 16 and a charger 18. The processing unit 12 includes one or more DSP chips and/or analog circuitry. Thus, depending on the embodiment, there can be digital and/or analog signal processing. The power unit 16 is preferably rechargeable and can include, for example a plurality of rechargeable NiMH cells. The power unit 16 delivers power to the processing unit 12 and the VU meter 14. The charger 18 delivers a charge to the power unit 16. The charger 18 plugs into a standard wall outlet and has a transformer, as well as a full-wave rectifier which produce a peak voltage of approximately 20 volts. The charger 18 further includes a fuse, such as a 250 mA fuse.

The signal processing system 10 further includes a housing 20 to protect components therein. On a first side of the housing 20, a charger input jack 22 is located. The charger input jack 22 is connected to the power unit 16 and connects with the charger 18 to deliver a charge to the power unit 16. On a second side of the housing 20, first and second program sockets 24, 26 are disposed. The first and second program sockets 24, 26 are used to re-program the processing unit 12. The processing unit 12 can be re-programmed with appropriate cables attached to the first and second program sockets 24, 26 to deliver programming from, for example, software running on a computer.

The housing 20 of the digital signal processing system 10 has a power switch 28 disposed on a front side that turns on the power for the processing unit 12 and the VU meter 14. The housing 20 further has an input socket 32 and an output socket 34. The input socket 32 can be, for example, a 3.5 mm stereo jack socket. The input socket 32 delivers an audio signal to other components in the signal processing system 10. The housing further has a selector switch 30 on the front side. The selector switch 30 can be moved into three distinct positions that correspond with three distinct modes: direct, standby and DSP. When the selector switch 30 is in the direct position, an audio signal is routed directly from the input socket 32 to the output socket 34 with no processing. The output socket 34 can be, for example, a 3.5 mm stereo jack socket and is compatible with most headsets. When the selector switch 30 is in the standby position, the signal is disconnected without having to turn off the power. When the selector switch 30 is in the DSP position, the audio signal is routed through a stereo input potentiometer 33 and the processing unit 12. The stereo input potentiometer 33 at the left of the panel operates only when the selector switch 30 is in the DSP position.

In addition, a stereo-mono switch 36 is disposed on the housing 20. When the signal processing system 10 is used with stereophonic recordings, this switch can be used to demonstrate a subtle improvement in comfort and clarity in the stereo position. The switch operates in direct and DSP modes. At least two program selectors 38 are disposed on the housing 20 to provide independent selection of programs for each channel. In this embodiment, the signal processing system 10 has four different programs. Program 1 is the default program and provides a flat frequency response. Selection of Program 1 is confirmed by one beep dispersed for the user. Program 2 (HF boost) causes the signal processing system 10 to operate at 10 dB at 6 kHz. Selection of Program 2 is confirmed by two high pitched beeps, for example. Program 3 (LF boost) causes the signal processing system 10 to operate at ±5 dB at 250 Hz. Confirmation for selection of Program 3 is accomplished by dispersing three low pitched beeps, for example. Program 4 is a LF and HF boost plus 5 dB middle cut.

The VU meter 14 is disposed on a top side of the housing 20. The VU meter 14 is calibrated and color coded to allow the audio signal to be monitored. In the embodiment shown, the VU meter 14, has indicators for various decibels between −20 dB and +3 dB. The VU meter 14 can also indicate the currently selected mode. For example, when the selector switch 30 is in the DSP position, a green LED at the −20 dB position of the VU meter 14 is permanently on.

### Example 1

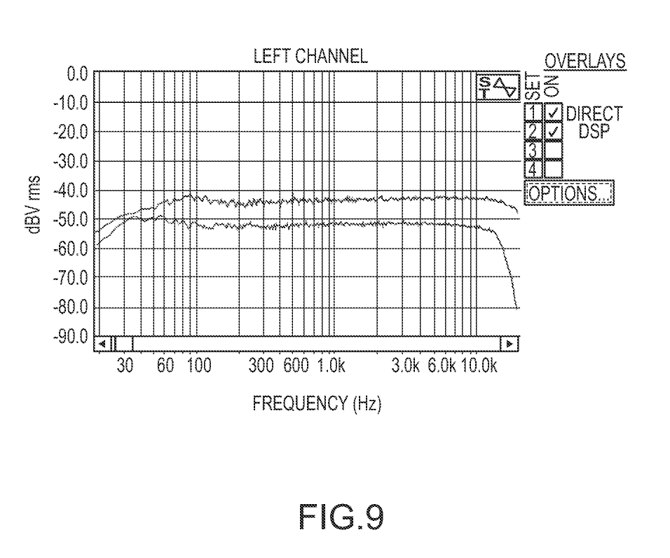

The present system and method of the present invention limits transient peak levels, improves listening comfort and allows an increased loudness sensation and clarity with less harmful sound pressure levels. FIG. 9 provides a graph of a white noise frequency spectrum of a Philips SA2115 pocket MP3 player (top line) loaded by an Able Planet Clear Harmony behind the head headset and the processing unit 12 of the system 10 (bottom line) loaded by the same headset. The output of the Processing unit 12 of the system 10 is about 9 dB lower at high input levels but higher at low input levels. The sound files that are pre-loaded on the MP3 player serve to show how dynamic signals such as speech and music are processed quite differently than continuous signals.

### Example 2

In this example, the power was switched on and the program selectors 38 were not pressed. The stereo input potentiometer 33 was set at maximum. Using the MP3 player to play a 500 Hz pure tone in Direct mode, the gain of the MP3 player was turned up until the LED on the VU meter 14 corresponding to a level of +1 dB was lit.

The selector switch 30 was then switched to the DSP mode. The signal then dropped to −20 dB or less: The sound was much quieter and severely distorted. Reducing the input potentiometer 8 dB (40% of maximum or about 11 o'clock on the dial position) eliminated the distortion and the DSP signal remains more than 20 dB below the direct signal. This illustrates that with the present invention, single frequencies focused on a narrow area on the basilar membrane in the inner ear will be drastically reduced without distortion. In a worst case scenario, the energy is redistributed across the membrane due to sound energy being redistributed to odd order harmonics (3rd harmonic distortion).

The distortion heard with the pure tone is due to peak clipping when the input level is beyond the limits of the DSP amplifier input. Note that distortion is only noticeable with pure tone signals. Most music and speech can tolerate 8 dB of peak clipping without audible distortion due to the brief nature of transient signals in the upper 8 dB (60%) of the signal level.

### Example 3

Using the MP3 player to play a white noise signal in Direct Mode and with the input potentiometer 33 set to maximum, the gain of the MP3 player was adjusted until the LED on the VU meter 13 corresponding to a level of +1 dB was lit. When switched to the DSP mode, the level dropped to only −7 dB but the sound energy is safely distributed across the whole length of the basilar membrane. Thus, the present invention contributes an additional 8 dB (60%) reduction in stress on the individual hair cells in the inner ear.

### Example 4

In this example, the gain of the MP3 player was set at the level used for the 500 Hz tone (Example 2) and White Noise (Example 3) and set the input potentiometer 33 to maximum. A good quality recording of “Colonel Bogey” music sample repeated 10 times in stereo was played using the MP3 player and, in the Direct mode, the kettle drums near the beginning of the recording were at about −20 dB on the VU meter 14. In the DSP mode, the VU meter 14 read 13 db higher (−7 dB) and the drums were louder. In both modes, the highest level reached was +1 dB although the DSP signal sounded louder and clearer due to greater amplification of the normally quiet components.

### Example 5

Example 4 was repeated playing a poor quality recording of a speech by Prince Philip repeated 10 times in mono using the MP3 player. Peak levels for the direct and DSP modes were equal but speech sounded louder and clearer in the DSP mode despite the fact that a critical ear may detect distortion at times.

In regards to DSP processing, the DSP processing works in three ways. First, at very high levels there is instantaneous peak clipping. Second, below peak clipping levels there is fast peak reduction that is relatively free of distortion. Third, a slow peak detector reduces the long term average peak level of the signal.

Regarding hearing protection, instantaneous peak clipping ensures that the ear is protected from loud transients. Brief transients are particularly damaging to the hair cells in the inner ear because they do not sound as loud as they really are (due to insufficient integration time in the auditory system) and listeners tend to over-expose their ears to harmful sound pressure levels. Although peak clipping produces distortion components they are not noticeable because they are as brief as the transients from which they are derived.

Fast peak reduction with a finite time constant improves the range of peak reduction by operating slowly enough that only relatively infrequent low frequency signals will be distorted.

Hearing research shows that signals at levels of 85 to 90 dB are quite safe when they occur briefly but can cause hearing loss if presented to the ear for long periods. The present invention monitors and reduces long term peak levels.

Regarding sound quality, the slow response peak detector ensures that the dynamic integrity of speech components is retained in vowels. Vowel components remain at their relative levels, but weak consonants are boosted. In music the weaker instruments are boosted and there is less forward masking by loud instruments. The reduction in forward masking also applies in speech.

A key feature of the present invention is that the raising of average peak levels allows the ear to perform at sound pressure levels where the frequency range is wider, but without the discomfort of high-level peaks of narrow frequency bandwidth.

In noisy conditions such as in automobiles and airplanes the long-term average peak level of hearing aids is reduced, thereby improving comfort and protecting the ear from fatigue. Speech can still be heard from all directions because it is natural to raise the voice above the noise in those conditions.

In understanding the scope of the present invention, the term “comprising” and its derivatives, as used herein, are intended to be open ended terms that specify the presence of the stated features, elements, components, groups, and/or steps, but do not exclude the presence of other unstated features, elements, components, groups, integers and/or steps. The foregoing also applies to words having similar meanings such as the terms, “including”, “having” and their derivatives. The terms of degree such as “substantially”, “about” and “approximate” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. For example, the size, shape, location or orientation of the various components can be changed as needed and/or desired. Components that are shown directly connected or contacting each other can have intermediate structures disposed between them. The functions of one element can be performed by two, and vice versa. The structures and functions of one embodiment can be adopted in another embodiment. It is not necessary for all advantages to be present in a particular embodiment at the same time. Thus, the foregoing descriptions of the embodiments according to the present invention are provided for illustration only, and not for the purpose of limiting the invention as defined by the appended claims and their equivalents.

What is claimed is:

1. A signal processing method for auditory enhancement and hearing conservation comprising:
controlling an audio signal having high intensity peaks;
clipping the audio signal by limiting peak power to produce a clipped signal; and
amplifying the clipped signal.

2. The method of claim 1, wherein the amplifying produces a signal overdriven by 10 dB.

3. The method of claim 1, wherein no feedback loop is used in the method.

4. The method of claim 1, wherein the clipping includes 10 dB clipping.

5. The method of claim 1, wherein the clipping and the amplifying enhances vowel/consonant ratio.

6. The method of claim 1, wherein the clipping and the amplifying are performed by one or more DSP chips.

7. The method of claim 1, wherein the clipping and the amplifying are performed by analog circuitry.

8. A signal processing system for auditory enhancement and hearing conservation comprising:
a processing unit for controlling an audio signal having high intensity peaks;
a power unit connected to the processing unit to deliver power;
an input socket operably connected to the processing unit and configured to receive the audio signal; and
an output socket operably connected to the processing unit and configured to output a processed audio signal, the processing unit being configured to clip the audio signal by limiting peak power to produce a clipped signal and being further configured to amplify the clipped signal.

9. The system of claim 8, further comprising a selector switch for selecting between processing the audio signal and not processing the audio signal, wherein the selector switch is arranged and configured to cause the system to process the audio signal or not process the audio signal depending on the position of the selector switch.

10. The system of claim 8, further comprising a program selector for selecting between two or more programs performed by the processing unit.

11. The system of claim 8, further comprising at least one program socket connected to the processing unit and configured to be utilized to program the processing unit.

12. The system of claim 8, further comprising a VU meter having a display for displaying characteristics of the audio signal.

13. The system of claim 8, wherein the output socket is compatible with a headset.

14. The system of claim 8, wherein the power unit is rechargeable.

15. The system of claim 8, wherein the processing unit includes one or more DSP chips.

16. The system of claim 8, wherein the processing unit includes analog circuitry.
